(19) United States
(12) Patent Application Publication
(10) Pub. No.: US 2019/0363520 A1
(43) Pub. Date: Nov. 28, 2019

(54) Vertical Emitters Integrated on Silicon Control Backplane

(71) Applicant: APPLE INC., Cupertino, CA (US)

(72) Inventors: Arnaud Laflaquiere, Singapore (SG); Marc Drader, Waterloo (CA)

(21) Appl. No.: 16/331,991

(22) PCT Filed: Sep. 18, 2017
(86) PCT No.: PCT/US2017/051948

§ 371 Date: Mar. 11, 2019

Related U.S. Application Data
(60) Provisional application No. 62/396,253, filed on Sep. 19, 2016.

(51) Int. Cl. H01S 5/42; H01S 5/022; H01L 25/16; H01S 5/02; H01S 5/183

(52) U.S. Cl. CPC H01S 5/423; H01S 5/02276; H01L 25/167; H01S 5/0261; H01S 5/0215; H01S 5/18388; H01S 5/021

(57) ABSTRACT

A method for manufacturing includes fabricating an array (22) of vertical emitters (32) by deposition of multiple epitaxial layers on a III-V semiconductor substrate (20), and fabricating control circuits (30) for the vertical emitters on a silicon substrate (26). Respective front sides (52) of the vertical emitters are bonded to the silicon substrate in alignment with the control circuits. After bonding the respective front sides, the III-V semiconductor substrate is thinned away from respective back sides (50) of the vertical emitters, and metal traces (78) are deposited over the vertical emitters to connect the vertical emitters to the control circuits.

### CROSS-REFERENCE TO RELATED APPLICATION

This application claims the benefit of U.S. Provisional Patent Application 62/396,253, filed Sep. 19, 2016, which is incorporated herein by reference.

### FIELD OF THE INVENTION

The present invention relates generally to semiconductor devices, and particularly to optoelectronic devices and methods for their manufacture.

### BACKGROUND

In conventional, top-emitting optoelectronic devices, such as vertical-cavity surface-emitting lasers (VCSELs), the semiconductor substrate serves not only as the base for fabrication of the emitters, but also as the mechanical supporting carrier of the emitter devices after fabrication. The terms “top” and “front” are used synonymously in the present description and in the claims in the conventional sense in which these terms are used in the art, to refer to the side of the semiconductor substrate on which the VCSELs are formed (typically by epitaxial layer growth and etching). The terms “bottom” and “back” refer to the opposite side of the semiconductor substrate. These terms are arbitrary, since once fabricated, the VCSELs will emit light in any desired orientation.

Bottom-emitting VCSEL devices are also known in the art. In such devices, after fabrication of the epitaxial layers on a wafer substrate (such as a GaAs wafer), the substrate is thinned away below the emitting bottom surfaces of the VCSELs. The top surfaces are typically attached to a heat sink, which can also provide mechanical support.

### SUMMARY

Embodiments of the present invention that are described hereinbelow provide improved optoelectronic devices and methods for their production.

There is therefore provided, in accordance with an embodiment of the invention, a method for manufacturing, which includes fabricating an array of vertical emitters by deposition of multiple epitaxial layers on a III-V semiconductor substrate, and fabricating control circuits for the vertical emitters on a silicon substrate. Respective front sides of the vertical emitters are bonded to the silicon substrate in alignment with the control circuits. After bonding the respective front sides, the III-V semiconductor substrate is thinned away from respective back sides of the vertical emitters. After thinning the III-V semiconductor substrate, metal traces are deposited over the vertical emitters to connect the vertical emitters to the control circuits.

In some embodiments, fabricating the array of vertical emitters includes, after thinning the III-V semiconductor substrate, etching the epitaxial layers to define individual emitter areas, and processing the emitter areas to create vertical-cavity surface-emitting lasers (VCSELs).

Additionally or alternatively, the method includes dicing the III-V semiconductor substrate into stamps, each containing one or more of the vertical emitters, wherein bonding the respective front sides includes aligning and bonding each of the stamps in a respective location on the silicon substrate.

Further additionally or alternatively, fabricating the array includes depositing a metal layer over the front sides of the vertical emitters, wherein the metal layer serves as a first contact between the front sides of the vertical emitters and the control circuits, while the metal traces serve as a second contact between the control circuits and the back sides of the vertical emitters.

In a disclosed embodiment, bonding the respective front sides includes applying a polymer glue between the front sides of the vertical emitters and the silicon substrate. Alternatively, fabricating the array includes depositing a metal layer over the front sides of the vertical emitters, and wherein bonding the respective front sides includes bonding the metal layer on the front sides of the vertical emitters to a further metal layer deposited on the silicon substrate in a metal-to-metal bond. Further alternatively, bonding the respective front sides includes forming an oxide bond between the front sides of the vertical emitters and the silicon substrate.

In some embodiments, depositing the metal traces includes attaching individual contacts to the vertical emitters, so that each of the vertical emitters is individually controllable by the control circuits. Additionally or alternatively, depositing the metal traces includes attaching respective shared contacts to predefined groups of the vertical emitters, so that each of the groups is collectively controllable by the control circuits. Typically, at least some of the deposited metal traces extend between the back sides of the vertical emitters and the control circuits on the silicon substrate.

In the disclosed embodiments, the method includes, after depositing the metal traces, dicing the silicon substrate to form a plurality of chips, each chip including one or more of the vertical emitters and the control circuits that are connected to the one or more of the vertical emitters.

In some embodiments, the method includes fabricating photodetectors on the silicon substrate, in locations chosen so that after bonding the respective front sides of the vertical emitters to the silicon substrate, the photodetectors are located alongside the vertical emitters on the chips. In a disclosed embodiment, fabricating the photodetectors includes arranging the photodetectors on the silicon substrate in a matrix geometry, and forming readout circuits on the silicon substrate, coupled to the photodetectors, so as to output image data from each chip.

Additionally or alternatively, the method includes forming microlenses on back sides of the vertical emitters.

There is also provided, in accordance with an embodiment of the invention, an optoelectronic device, including a silicon substrate and control circuits fabricated on the silicon substrate. An array of vertical emitters includes multiple epitaxial layers formed on a III-V semiconductor substrate. The vertical emitters have respective front sides that are bonded to the silicon substrate in alignment with the control circuits and being configured to emit radiation through respective back sides of the vertical emitters. Metal traces are disposed over the vertical emitters and connecting the vertical emitters to the control circuits.

The present invention will be more fully understood from the following detailed description of the embodiments thereof, taken together with the drawings in which:

### BRIEF DESCRIPTION OF THE DRAWINGS

FIGS. 1A-F schematically illustrate stages in fabrication of a VCSEL-based projector, in accordance with an embodiment of the invention;

FIG. 2 is a schematic sectional view of layers in a VCSEL, in accordance with an embodiment of the invention;

FIGS. 3A-C are schematic sectional views showing stages in production of a VCSEL device, in accordance with an embodiment of the invention;

FIG. 4A is a schematic sectional view of an array of VCSELs with integrated electrical connections, in accordance with an embodiment of the invention;

FIG. 4B is an electrical schematic diagram of a VCSEL array and control circuits, in accordance with an embodiment of the invention;

FIGS. 5A and 5B are schematic sectional views of arrays of VCSEL devices with integrated electrical connections, in accordance with further embodiments of the invention;

FIG. 6 is a schematic sectional view of an array of VCSEL devices with integrated electrical connections, in accordance with yet another embodiment of the invention;

FIGS. 7A-C are schematic sectional views of arrays of VCSEL devices with integrated electrical connections, in accordance with still other embodiments of the invention;

FIGS. 7D-F are schematic top views of the arrays of FIGS. 7A-C, respectively;

FIGS. 8A and 8B are schematic sectional views of arrays of VCSEL devices with integrated electrical connections, in accordance with alternative embodiments of the invention;

FIGS. 9A and 9B are schematic top views of shared electrical contacts, in accordance with embodiments of the invention;

FIG. 10 is a schematic sectional view of a VCSEL with an integrated microlens, in accordance with an embodiment of the invention;

FIG. 11A is a schematic side view of a projector based on a VSEL array, in accordance with an embodiment of the invention;

FIGS. 11B-D are schematic side views of integrated projector and detector arrays, in accordance with alternative embodiments of the invention;

FIG. 12 is a schematic sectional view of an integrated projector and detector array, in accordance with an alternative embodiment of the invention; and

FIGS. 13A and 13B are schematic sectional and top views, respectively, showing integrated VCSEL arrays and control circuits fabricated on a semiconductor substrate, in accordance with an embodiment of the invention.

### DETAILED DESCRIPTION OF EMBODIMENTS

Among semiconductor optoelectronic devices, vertical emitters, such as VCSELs, offer advantages of high output power and convenient optical geometry, as well as wafer-level fabrication and testing. Existing processes for bonding the emitters to heat sinks and control circuits, however, are complex and costly.

The embodiments of the present invention that are described hereinbelow provide improved methods for wafer-scale production of emitters and emitter arrays, as well as optoelectronic devices produced by such methods. The emitters are integrated with control circuits in a single chip, which is formed by bonding together a III-V semiconductor substrate on which the emitters are fabricated with a silicon substrate on which control circuits for the emitters are fabricated.

In some embodiments, photodetectors are fabricated on the silicon substrate, as well, alongside the locations of the emitters. Readout circuits may be formed on the substrate and coupled to the photodetectors so as to output image data, thus providing an integrated illuminator and camera on a single chip. This sort of integrated device can be used, for example, to project patterned light onto a target and capture an image of the projected pattern for purposes of depth mapping.

In the embodiments that are described hereinbelow, for the sake of concreteness and clarity, the III-V semiconductor substrate is assumed to be a GaAs wafer, and the vertical emitters are assumed to be VCSELs, comprising multiple epitaxial layers deposited on the GaAs substrate. It is also assumed that the control circuits are fabricated using a CMOS process, as is known in the art (in which case the photodetectors used in some embodiments may conveniently comprise photodiodes formed by the CMOS process). The principles of the present invention may alternatively be applied, however, in producing other types of vertical emitters and/or using other sorts of III-V substrates, as well as other silicon fabrication processes, as will be apparent to those skilled in the art after reading the present description. All such alternative embodiments are considered to be within the scope of the present invention.

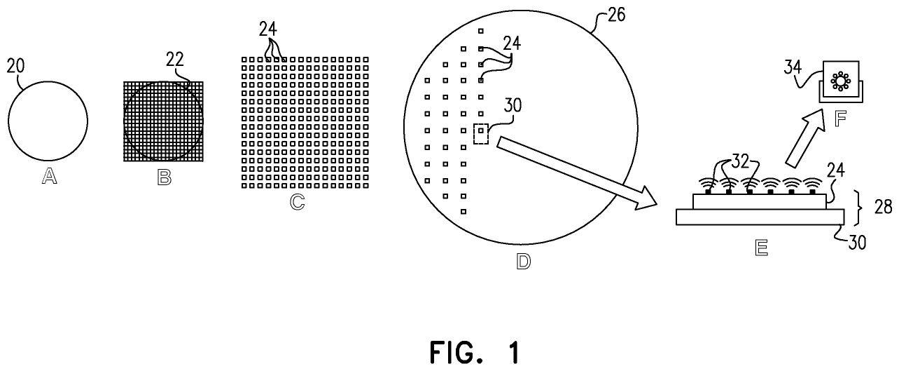

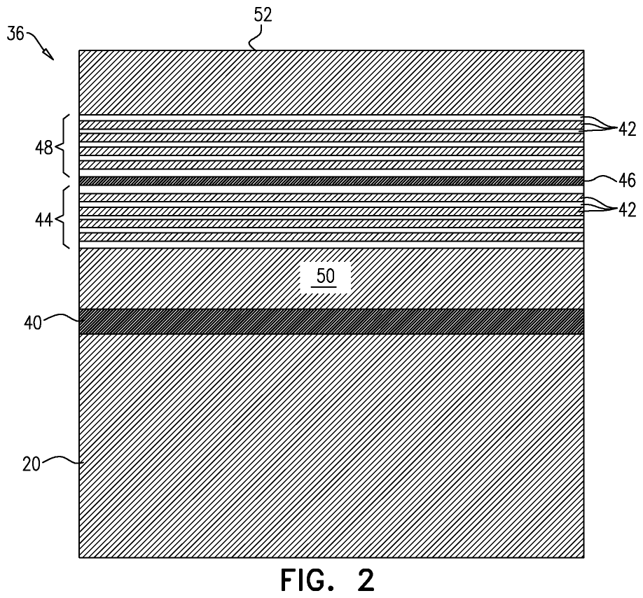

FIGS. 1A-F schematically illustrate stages in fabrication of a VCSEL-based projector 34, in accordance with an embodiment of the invention. The process begins with a III-V semiconductor substrate 20, such as a GaAs wafer, on which multiple epitaxial layers are deposited as the basis for an array 22 of VCSELs 32 (as shown in detail in FIG. 2). In preparation for bonding to a silicon wafer substrate with control circuits, the GaAs wafer is diced into “stamps” 24 (i.e., small chips), each containing one or more of the VCSELs. Alternatively, the entire GaAs may be bonded onto the silicon wafer before any dicing, although this option is constrained by the difference in size between standard VCSEL-process GaAs wafers (typically 3-6″) and standard CMOS-process silicon wafers (8-12″). This latter process option also requires extra care due to the difference in coefficients of thermal expansion between GaAs and silicon.

In a separate step, control circuits 30 for the vertical emitters are formed on a silicon substrate 26, using a CMOS process, for example. The front sides of VCSEL stamps 24 are then bonded to silicon substrate 26, with each VCSEL in alignment with its respective control circuits 30. Techniques that can be used in this bonding step are described hereinbelow. After bonding the front sides of the VCSEL stamps to the silicon wafer, the GaAs substrate is thinned away from the back sides, and the VCSELs may be further etched to a desired shape, such as mesas, as are known in the art. Metal traces are then deposited over the VCSELs in order to serve as contacts in connecting the VCSELs to the control circuits on the silicon wafer. Various options for forming these traces are described with reference to the figures that follow.

After depositing the metal traces, the silicon substrate is diced into separate chips 28. Depending on the number of VCSELs 32 in each stamp 24, each chip comprises one or more VCSELs and the CMOS control circuits 30 that are connected to the VCSELs. Chips 28 can then be individually tested and packaged as desired in projectors 34 or other devices. Projector 34 emits illumination that may be modulated by the control circuits in a desired spatial and/or temporal pattern.

FIG. 2 is a schematic sectional view of epitaxial layers in a VCSEL 36, in accordance with an embodiment of the invention. A front (or top) side 52 is facing up, while a back (or bottom) side 50 faces down. As a preliminary stage in fabricating the VCSEL, an etch stop layer 40, such as a thin layer of GaInP, is generally formed over substrate 20, which comprises a suitable semiconductor material, such as GaAs. Alternating high- and low-index layers 42 are then epitaxially grown to define a first distributed Bragg grating (DBR) 44, followed by a quantum well (QW) layer 46, and then by a second DBR 48 grown over the upper side of the QW layer. As noted earlier, top side 52 of the VCSEL structure will then be bonded (for example, with a suitable polymer glue) to silicon wafer 26, and radiation will be emitted from bottom side 50 after substrate 20 has been thinned away.

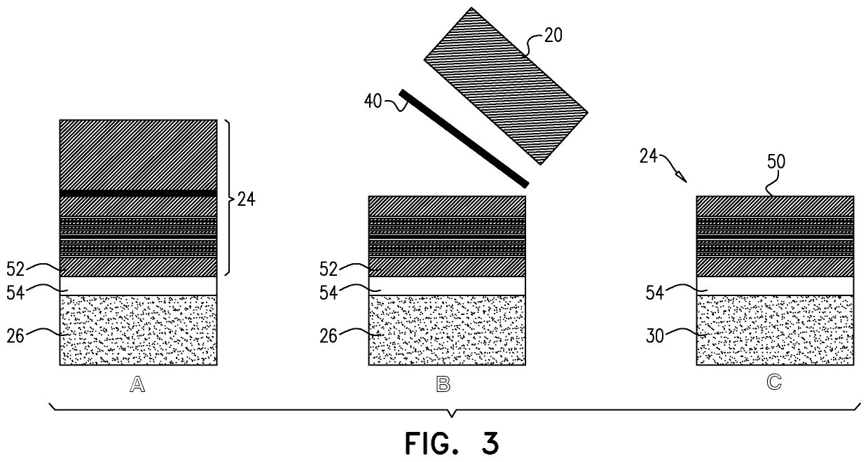

FIGS. 3A-C are schematic sectional views showing subsequent stages in production of an integrated VCSEL device, in accordance with an embodiment of the invention. VCSEL stamps 24 are formed, as described above, by growth of suitable epitaxial layers followed by dicing. Front side 52 of each stamp is then bonded to silicon wafer 26, in alignment with the control circuits on the silicon wafer that are to drive and control the VCSELs. In this example, a polymer glue 54 is used to bond the stamp to the wafer, but other bonding techniques may alternatively be used as described hereinbelow.

After all of VCSEL stamps 24 have been bonded to silicon wafer 26, GaAs substrate 20 is thinned away from the back sides of all the VCSELs, typically by mechanical and chemical etching techniques that are known in the art. Etch stop layer 40 may then be removed, as well, using a different etchant. Following this step, only the epitaxial VCSEL layers remain, bonded by their front side 52 to silicon wafer 26, which is then diced to produce chips 30. The total thickness of the VCSEL layers is typically less than 15 μm. In addition to the small device dimensions, the thin VCSEL structure with the front side bonded securely to the silicon wafer enable effective heat-sinking to the silicon wafer during VCSEL operation.

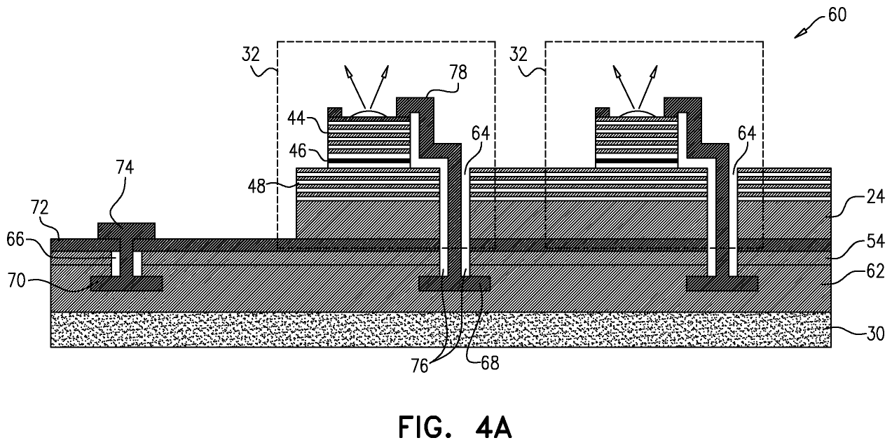

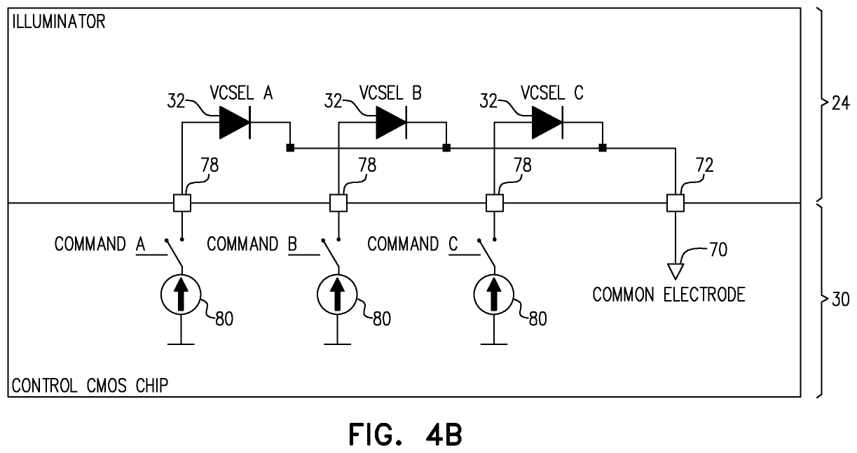

FIG. 4A is a schematic sectional view of an array 60 of VCSELs 32 with integrated electrical connections, in accordance with an embodiment of the invention. In this figure, VCSEL stamp 24 is used to produce an array of individual VCSELS 32, by etching upper epitaxial layers 44 (after bonding front side 52 to the silicon substrate) so as to define individual VCSEL mesas. In this step, individual emitter areas are etched and processed into VCSELs 32 (for example by confinement through lateral oxidation, or proton implantation or other techniques that are known in the art). Vias 64 are etched through the remaining epitaxial layers in order to reach electrical contacts 68 in underlying silicon chip 30. The etch pattern at this stage depends on the desired density of VCSELs in the array and the electrical drive configuration. Each VCSEL requires two electrical drive contacts, one on the front side (the lower side of the VCSELs in the orientation shown in FIG. 4A) and the other on the back. These drive contacts can be individual or shared among multiple VCSELs, as described hereinbelow.

In the present example, a metal layer 72 was formed over front side 52 of the VCSEL structure, above the epitaxial layers shown in FIG. 2, before bonding to silicon wafer 26. After bonding, this metal layer 72 serves as a common contact between the front sides of the VCSELs and the control circuits on the silicon wafer. Metal layer 72 on the front side of VCSELs 32 is connected to appropriate contact terminals 70 in the upper metal layer of the patterned silicon wafer, for example by etching a via 66 through to contact terminals 70 and depositing a metal contact 74 through the via. The contact terminals are typically disposed around the edges of VCSEL array 60, although it is also possible to make the connections within the array (at the cost of leaving less room for the VCSEL emitters themselves).

The back side of each VCSEL 32 (facing upward in FIG. 4A) is connected to an individual driver and possibly other control circuits on silicon chip 30 (as shown in FIG. 4B, for example), again via contact terminals 68 in the outer metal layer of the silicon wafer. This connection is made by depositing metal traces 78 over the back sides of the VCSELs after etching of the VCSEL structures. In the embodiment shown in FIG. 4A, vias 64 are etched through the epitaxial layers alongside each VCSEL, down to the locations of metal contact terminals 68 in an upper passivation layer 62 of the silicon wafer. An internal oxide lining layer 76 may be formed inside these vias for insulation from the surrounding VCSEL and metal layers. The remaining inner via is then filled with metal in order to complete the metal trace extending between the back side of the VCSEL and the control circuits on the silicon substrate. This individual contact to the back side of each VCSEL allows the control circuits on the silicon wafer to control each of the VCSELs individually, in accordance with any desired temporal and spatial pattern of projected radiation.

FIG. 4B is an electrical schematic diagram of an array of VCSELs 32 on stamp 24 and control circuits on chip 30, in accordance with an embodiment of the invention. This sort of circuit design can be realized using the structure of layers and contacts that is shown in FIG. 4A. The anode and cathode connection points, where traces 72 and 78 on the VCSEL illuminator stamp meet contact terminals 68 and 70 on the silicon CMOS control chip, are shown as squares along the horizontal border in the figure between the chips. The control circuits comprise current drivers 80, each of which controls a respective VCSEL anode individually through a respective switch (labeled command A, B, C, . . . ). All of the VCSELs are connected to a common cathode, with the connection made in this case via multiple connection points in order to minimize current-related voltage drops.

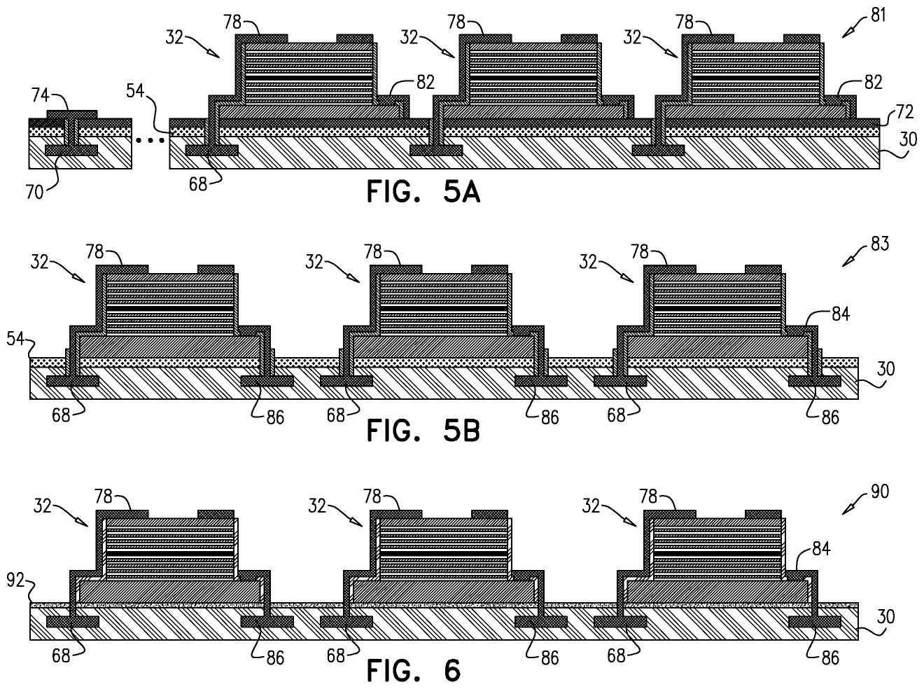

FIGS. 5A and 5B are schematic sectional views of arrays 81, 83 of VCSELs 32 with integrated electrical connections, in accordance with further embodiments of the invention Like the embodiment of FIG. 4A, the embodiments of FIGS. 5A and 5B are also suitable for implementation in processes in which the VCSEL stamp is bonded to silicon wafer 26 with polymer glue 54. In FIG. 5A, each VCSEL 32 has an individual anode contact formed by trace 78, while the common cathode formed by metal layer 72 is connected by contacts 82 at the bottom of the VCSEL mesas to terminals 70 in a metal layer around the periphery of the VCSEL array. By contrast, in FIG. 5B, each VCSEL 32 has its own, individual cathode contact 84 to a local terminal 86 in the underlying metal layer, along with anode contact formed by trace 78, in order to facilitate precise control.

FIG. 6 is a schematic sectional view of an array 90 of VCSELs 32 with integrated electrical connections, in accordance with yet another embodiment of the invention. In this case, front surface 52 of VCSEL stamp 24 is bonded to silicon wafer 26, by an oxide bonding process, to a layer 92 of SiO₂ at the upper surface of the silicon wafer. The electrode connections are as in FIG. 5B. The bonding is realized by SiO₂—SiO₂ connection, as is known in the art. Following this step, electrodes are formed through vias down to the underlying silicon. As SiO₂ is an insulator, it may be easier to form the vias than in the preceding embodiment, as there is no need for a liner of passivation before adding the metal for the connection.

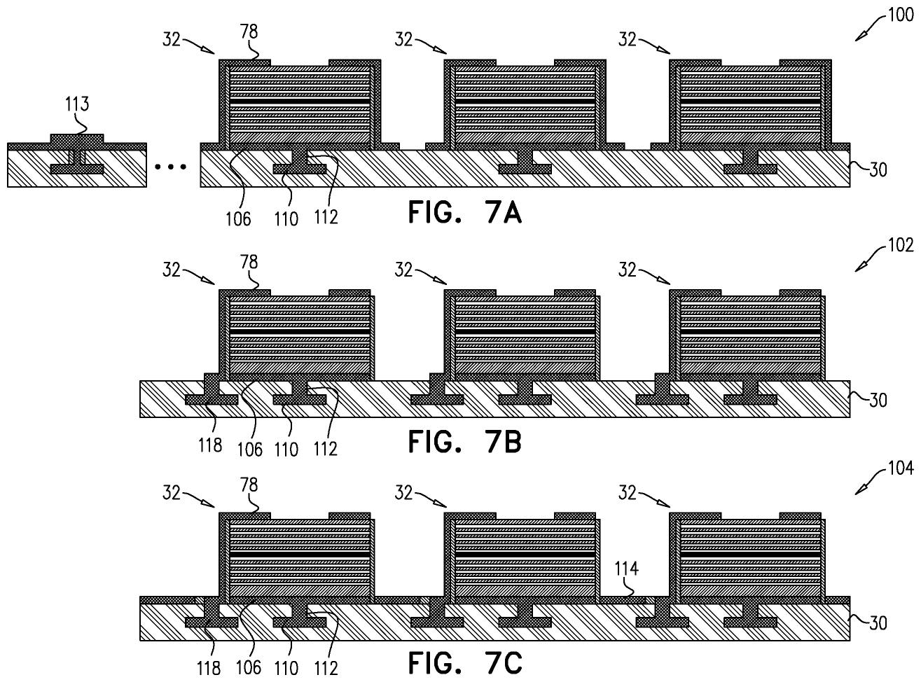

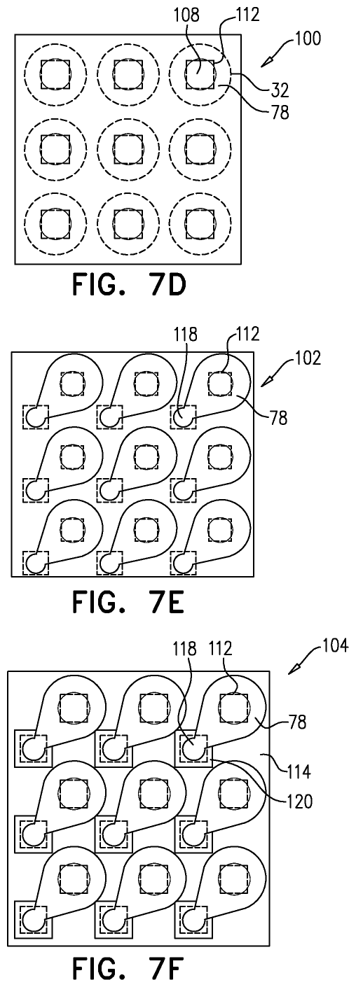

FIGS. 7A-C are schematic sectional views of arrays 100, 102, 104 of VCSELs 32 with integrated electrical connections, in accordance with still other embodiments of the invention, in which metal-to-metal bonding is used to attach the VCSEL stamps to the silicon wafer. FIGS. 7D-F are schematic top views of arrays 100, 102, 104, respectively, showing optical apertures 108 of VCSELs 32, surrounded by traces 78.

For the purpose of metal-to-metal bonding, a metal layer 106 is deposited over front sides 52 of the vertical emitters before VCSEL stamps 24 are diced apart. Metal layer 106 is then bonded to a corresponding metal layer deposited on silicon wafer 26 in a metal-to-metal bond and thus connects the lower side of each VCSEL 32 through a via 112 to an individual contact 110 in a metal layer of chip 30. For example, the metal layers may comprise copper, and these copper layers are then joined together by molecular bonding. To perform this sort of bonding, the metal surfaces are cleaned and pre-processed for low roughness, low density of particles, and de-oxidation. The surfaces are then bonded together under pressure, typically at elevated temperature. Equipment that can be used in the bonding process is offered by a number of suppliers.

In all of the embodiments of FIGS. 7A-F, each VCSEL 32 has an individual lower contact 110. In FIGS. 7A and 7D, the upper contacts formed by traces 78 are commonly connected to terminals 113 around the periphery of array 100, while in FIGS. 7B and 7E, each VCSEL 32 in array 102 has an individual upper contact 118. In the embodiment of FIGS. 7C and 7F, each VCSEL 32 in array 104 has its own upper contact 118, while lower contacts are connected to a common shared plate 114 for better efficiency. An insulating border 120 separates upper contacts 118 from plate 114.

Both gluing and molecular bonding between the VCSEL stamps and the silicon wafer have the advantage, inter alia, of working acceptably well even with low-precision placement of the VCSEL stamps on the silicon wafer. Polymer glue can also adapt to uneven bonding surfaces. Alternatively, other bonding techniques (not shown in the figures) can be used. For example, metal circuit contacts on the VCSEL stamp can be bonded to copper pillars that are exposed at the upper surface of the silicon wafer and connect to control circuits on the wafer. This approach requires more precise placement of the VCSEL stamps but is advantageous in reducing or eliminating the subsequent process steps that are needed to make the electrical connections.

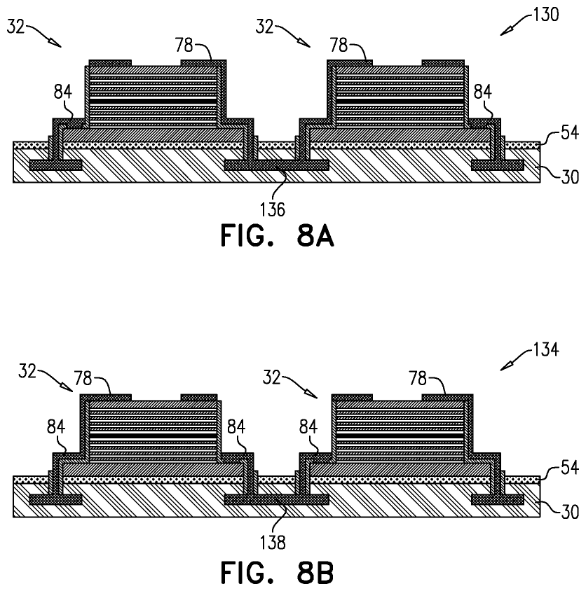

FIGS. 8A and 8B are schematic sectional views of arrays 130 and 134 of VCSELs 32 with integrated electrical connections, in accordance with alternative embodiments of the invention. In these embodiments, shared contacts 136, 138 are attached to predefined groups of the VCSELs, so that each of the groups is collectively controllable by the control circuits. Thus, neighboring VCSELs have either a shared anode contact 136 (FIG. 8A) or a shared cathode contact 138 (FIG. 8B). Sharing electrodes in this manner reduces the chip real estate that is occupied by the electrical traces and control circuits and thus makes it possible to reduce the pitch of the VCSEL array and achieve a higher density of VCSELs per unit area. The examples shown in FIGS. 8A and 8B assume polymer glue bonding of the VCSEL stamp to the silicon wafer, but the principles of these embodiments can similarly be applied using other types of bonds.

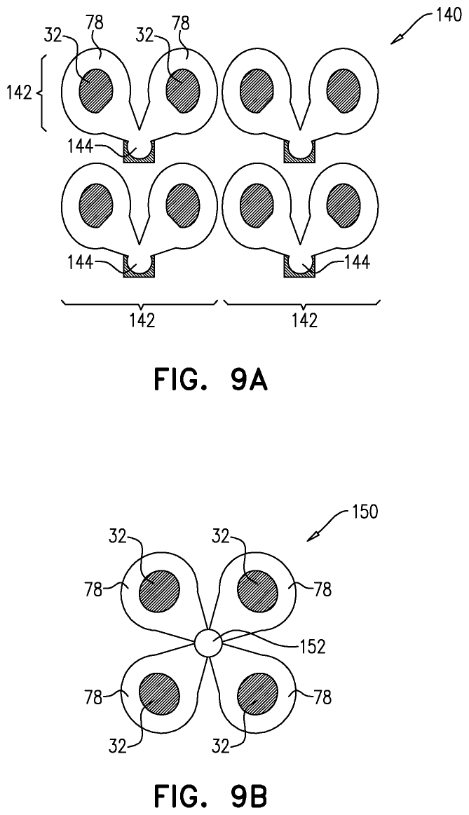

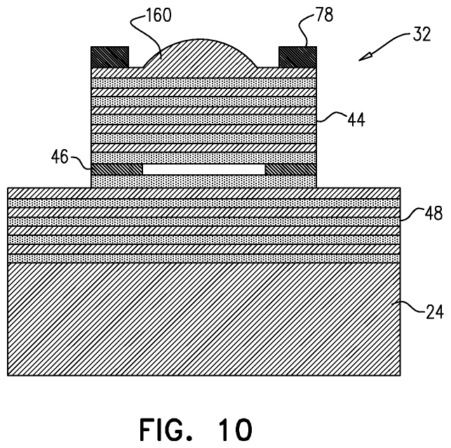

FIGS. 9A and 9B are schematic top views of arrays 140, 150 of VCSELs 32 with shared electrical contacts 144, 152, used in attaching groups of neighboring VCSELs to control circuits in the silicon wafer, in accordance with embodiments of the invention. In FIG. 9A, each pair 142 of neighboring VCSELs 32 shares a contact 144, while in FIG. 9B, four neighboring VCSELs 32 share the same contact 152. Assuming these to be the anode contacts, it is possible in these embodiments to connect a metal cathode layer on the front surface of the VCSELs to a corresponding metal layer on the silicon wafer by metal-to-metal bonding, for example, and thus achieve a particularly compact design.

FIG. 10 is a schematic side view of VCSEL 32 with an integrated microlens 160, in accordance with an embodiment of the invention. Such microlenses are formed on the back sides of the VCSELs after the VCSELs have been bonded to silicon wafer 26 and are advantageous in improving the collimation of the radiation emitted by the VCSEL. The microlenses may be made, for example, either from a transparent semiconductor material, such as GaAs, or from a polymer.

The use of GaAs to create microlens structures on the VCSELs has two notable advantages: The index of refraction of GaAs is greater than that of polymer and glass materials that are commonly used in microlens structures, so that a GaAs microlens will have higher optical power than a polymer or glass lens of similar dimensions. In addition, an existing GaAs layer in the VCSEL epitaxy stack can be used to form the microlenses, by etching the GaAs material to define the desired shape. This sort of etching can be carried out by a transfer process, for example, in which a polymer pattern is formed with the desired shapes of the microlenses, this pattern is applied to the wafer using a suitable resist, and finally the pattern is transferred into the GaAs layer by dry etching.

Alternatively, the microlenses can be patterned and formed on the back sides of the VCSELs using a polymer resist material. This sort of microlens will typically have less optical power, due to the lower refractive index compared to GaAs, but is relatively easy to produce using techniques that are known in the art.

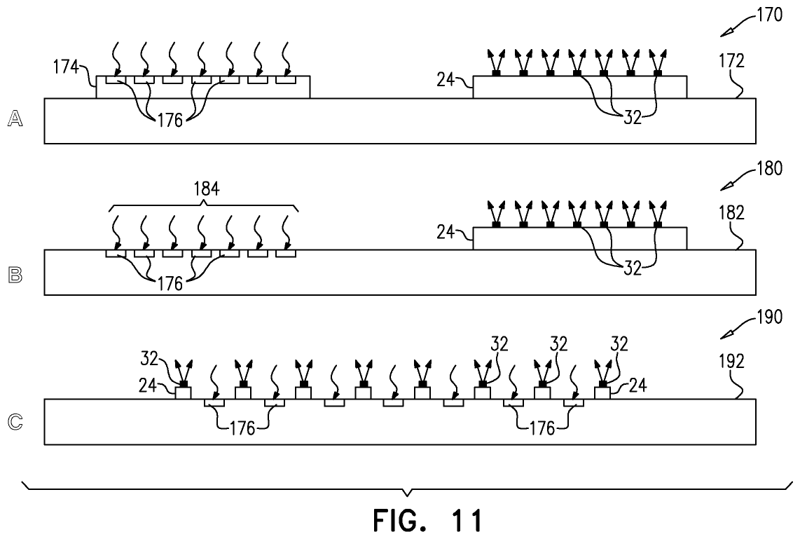

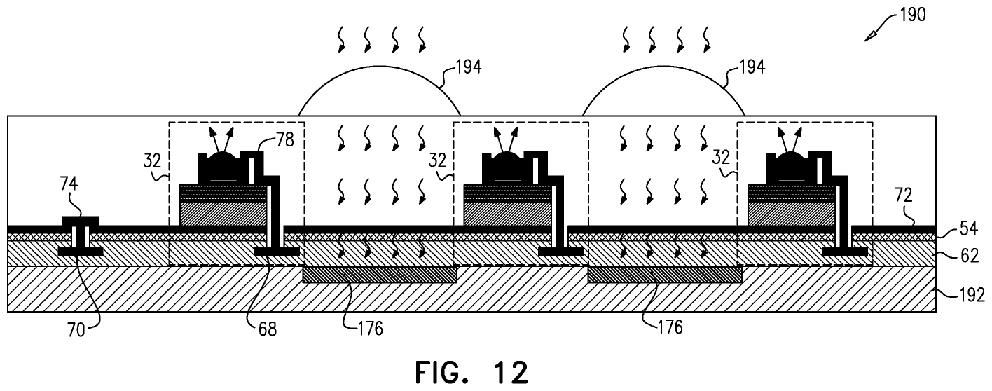

FIG. 11A is a schematic side view of an integrated projector and detector array 170, in accordance with another embodiment of the invention. In this case, an image sensor chip 174, comprising an array of optical detectors 176 is bonded onto a silicon control chip 172 alongside VCSEL stamp 24. Thus, the combined device shown in FIG. 11A includes both a projector and an image sensor on a single substrate. This sort of device can be used efficiently in a variety of applications, such as projection and imaging of structured light patterns for purposes of depth mapping.

FIGS. 11B and 11C are schematic side views of integrated projector and detector arrays 180, 190, in accordance with alternative embodiments of the invention. In these embodiments, photodetectors 176, such as CMOS photodiodes, are fabricated on silicon chips 182, 192 together with the control circuits, before bonding to VCSEL stamps 24. The locations of photodetectors 176 are chosen so that after bonding the respective front sides of the VCSEL stamps to the silicon substrate, the photodetectors will be located alongside VCSELs 32 on the chips. In FIG. 11B, a matrix 184 of photodetectors 176 is formed in a dedicated area of silicon chip 182, alongside the area where VCSEL stamp 24 is attached. In FIG. 11C, on the other hand, photodetectors 176 are interleaved with VCSELs 32.

In these embodiments, it is possible to arrange the photodetectors on the silicon substrate in a matrix geometry, as in an image sensor. In addition, readout circuits (not shown) are formed on the silicon substrate and are coupled to the photodetectors so as to output image data from each chip.

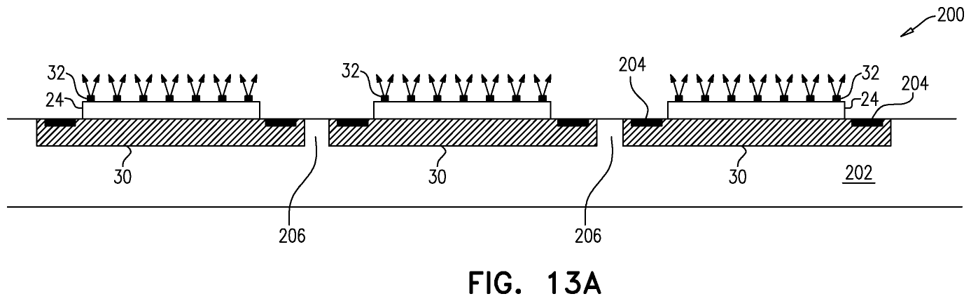

FIG. 12 is a schematic sectional view of integrated projector and detector array 190, in accordance with an alternative embodiment of the invention. This figure shows details of a possible implementation of the architecture illustrated in FIG. 11C. Photodetectors 176 have the form of photodiodes, which are fabricated at the upper surface of the silicon substrate, at locations that are interleaved with the locations at which VCSELs 32 are subsequently fixed.

Microlenses 194 can be formed over the locations of the photodiodes, as shown in FIG. 12, in order to improve light collection efficiency. These microlenses may be formed from a polymer layer deposited over the chip, or they may be etched from GaAs remaining between the VCSELs, in the manner described above. Optionally, additional microlenses may be formed over the VCSELs, as shown in FIG. 10, for example.

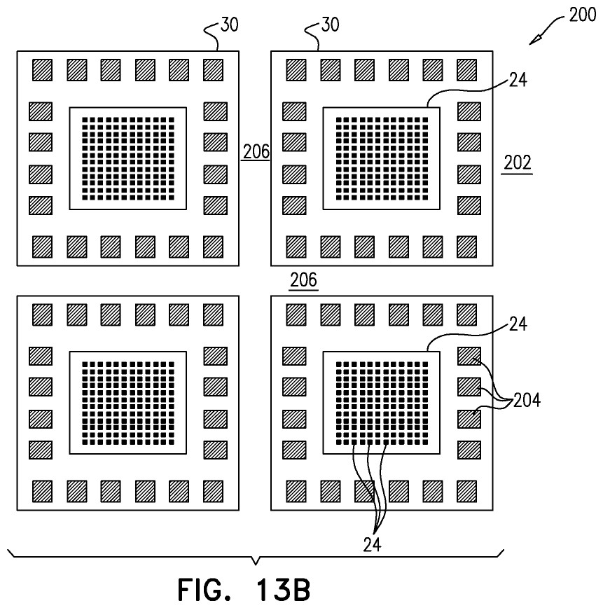

FIGS. 13A and 13B are schematic sectional and top views, respectively, showing integrated VCSEL arrays 200 and control circuits fabricated on a semiconductor substrate 202, in accordance with an embodiment of the invention. In fabricating the CMOS control circuits on the silicon wafer, “sawing streets” 206 are left between the borders of adjacent chips 30, and bonding pads 204 are deposited around the periphery of each chip. After VCSEL stamps 24 have been bonded and connected to the CMOS control circuits, as described above, silicon substrate 202 is then diced along these sawing streets to separate chips 30. As explained earlier, each chip in this embodiment comprises an array of VCSELs 32 and the control circuits that are connected to the VCSELs. Bonding pads 204 are used to connect chip 30 to the package leads or other components in an integrated device in which the chip is installed.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for manufacturing, comprising:
fabricating an array of vertical emitters by deposition depositing of multiple epitaxial layers on a III-V semiconductor substrate, including a first set of the layers defining a first distributed Bragg grating (DBR), a quantum well (QW) layer deposited over the first DBR, and a second set of the layers deposited over the QW layer and defining a second DBR;
dicing the III-V semiconductor substrate, with the multiple epitaxial layers deposited thereon, into stamps;
fabricating control circuits for an array of vertical-cavity surface-emitting lasers (VCSELs) on a silicon substrate;
aligning and bonding respective front sides of the stamps to the silicon substrate at respective locations in alignment with the control circuits;
after bonding the respective front sides, thinning the III-V semiconductor substrate away from respective back sides of the stamps;
after thinning the III-V semiconductor substrate, etching the epitaxial layers to define individual emitter areas, and processing the emitter areas to create the VCSELs; and
after etching and processing the emitter areas to create the VCSELs, depositing metal traces over respective back sides of the VCSELs to connect the VCSELs to the control circuits.

2-3. (canceled)

4. The method according to claim 1, wherein bonding the respective front sides comprises applying a polymer glue between the front sides of the stamps and the silicon substrate.

5. The method according to claim 1, wherein depositing the multiple epitaxial layers comprises depositing a metal layer over the front sides of the epitaxial layers, wherein the metal layer serves as a first contact between the front sides of the VCSELs and the control circuits, while the metal traces serve as a second contact between the control circuits and the back sides of the VCSELs.

6. The method according to claim 1, wherein depositing the multiple epitaxial layers comprises depositing a metal layer over the front sides of the epitaxial layers, and wherein bonding the respective front sides comprises bonding the metal layer on the front sides of the stamps to a further metal layer deposited on the silicon substrate in a metal-to-metal bond.

7. The method according to claim 1, wherein bonding the respective front sides comprises forming an oxide bond between the front sides of the stamps and the silicon substrate.

8. The method according to claim 1, wherein depositing the metal traces comprises attaching individual contacts to the VCSELs, so that each of the VCSELs is individually controllable by the control circuits.

9. The method according to claim 1, wherein depositing the metal traces comprises attaching respective shared contacts to predefined groups of the VCSELs, so that each of the groups is collectively controllable by the control circuits.

10. The method according to claim 1, wherein at least some of the deposited metal traces extend between the back sides of the VCSELs and the control circuits on the silicon substrate.

11. The method according to claim 1, and comprising, after depositing the metal traces, dicing the silicon substrate to form a plurality of chips, each chip comprising one or more of the VCSELs and the control circuits that are connected to the one or more of the VCSELs.

12. The method according to claim 11, and comprising fabricating photodetectors on the silicon substrate, in locations chosen so that after bonding the respective front sides of the VCSELs to the silicon substrate, the photodetectors are located alongside the VCSELs on the chips.

13. The method according to claim 12, wherein fabricating the photodetectors comprises arranging the photodetectors on the silicon substrate in a matrix geometry, and forming readout circuits on the silicon substrate, coupled to the photodetectors, so as to output image data from each chip.

14. The method according to claim 1, and comprising forming microlenses on back sides of the VCSELs.

15. An array of optoelectronic devices, comprising:
a silicon substrate;
control circuits for an array of vertical-cavity surface-emitting lasers (VCSELs) fabricated on the silicon substrate;
a plurality of stamps diced from a III-V semiconductor substrate comprising multiple epitaxial layers, including a first set of the layers defining a first distributed Bragg grating (DBR), a quantum well (QW) layer deposited over the first DBR, and a second set of the layers deposited over the QW layer and defining a second DBR, the stamps having respective front sides that are bonded to the silicon substrate in respective locations in alignment with the control circuits, wherein after bonding to the silicon substrate, the III-V semiconductor substrate of the stamps is thinned, and the epitaxial layers of the stamps are etched to define individual emitter areas and processed to create the VCSELs, which are configured to emit radiation through respective back sides thereof; and
metal traces disposed over respective back sides of the VCSELs and connecting the VCSELs to the control circuits.

16-17. (canceled)

18. The array of devices according to claim 15, wherein the metal traces are configured as individual contacts to the VCSELs, so that each of the VCSELs is individually controllable by the control circuits.

19. The array of devices according to claim 15, wherein the metal traces are configured as shared contacts, which are attached to respective groups of the VCSELs, so that each of the groups is collectively controllable by the control circuits.

20. The array of devices according to claim 15, and comprising photodetectors fabricated on the silicon substrate, in locations chosen so that after bonding the respective front sides of the stamps to the silicon substrate, the photodetectors are located alongside the stamps.
